(19) United States
(12) Patent Application Publication
(10) Pub. No.: US 2026/0191092 A1
(43) Pub. Date: Jul. 2, 2026

(54) SURFACE MOUNT TECHNOLOGY USING SUPPORTING MEMBER

(71) Applicant: Lenovo (Beijing) Limited, Beijing (CN)

(72) Inventors: Tadashi Kosuga, Kanagawa (JP); Tin-Lup Wong, Morrisville, NC (US); Yun Zhu, Beijing (CN); Hua Wang, Beijing (CN)

(73) Assignee: Lenovo (Beijing) Limited, Beijing (CN)

(21) Appl. No.: 18/853,869

(22) PCT Filed: Oct. 9, 2023
(86) PCT No.: PCT/CN2023/123515

§ 371 Date: Oct. 3, 2024

(51) Int. Cl. H10W 76/40; H10W 76/01; H10W 76/63; H10W 90/00

(52) U.S. Cl. CPC H10W 76/40; H10W 76/01; H10W 76/63; H10W 90/724

(57) ABSTRACT

A method of fabricating an electronic assembly (100,400) includes: forming a supporting member (130,430) by applying a first adhesive layer (133,433) to an interior surface of a supporting frame (131,431) and a second adhesive layer (134,434) to a bottom surface of the supporting frame (131,431) (S501); attaching, through the first adhesive layer (133,433), the supporting member (130,430) to a component (110,410) comprising a ball grid array of solder balls (111,411) (S502), such that the interior surface of the supporting frame (131,431) covers a portion of a first side surface of the component (110,410) and a portion of the bottom surface of the component (110,410); mounting, through the second adhesive layer (134,434), the supporting member (130,430) to a substrate (120,420) comprising an array of contact pads (121,421) whose pattern matches the ball grid array (S503); and curing the first adhesive layer (133,433) and the second adhesive layer (134,434) and connecting the solder balls (111,411) to the contact pads (121,421) by reflow soldering at a temperature higher than a melting point of the solder balls (111,411) (S504).

### BACKGROUND

Surface mount technology (SMT) is a technique to fabricate electronic assemblies, in which components are mounted directly onto a surface of a substrate, for example a printed circuit board (PCB). The components are designed specifically to be directly mounted, rather than hardwired, onto the substrate for a vast majority of electronics. SMT allows for increased manufacturing automation which reduces cost and improves quality, such as higher component density and smaller components for mounting alongside better performance under pressure.

A ball grid array (BGA) technique is a surface mount method, mostly used for flip chips as the need for high-density mounting increased. The BGA includes an array of small-size metallic solder balls arranged on a bottom surface of a component. Correspondingly, a substrate includes an array of contact pads having a same pattern that matches the solder balls. The placement of component onto the substrate is realized by reflow soldering process, in which the solder balls are heated to melt using, for example, a reflow oven or by an infrared heater. The surface tension causes the molten solder balls to hold the component in alignment with the substrate at a certain separation distance. After the solder balls cool and solidify, solder joints are formed between the component and the substrate.

The solder balls that connect the substrate and the components are prone to fracturing when subject to mechanical and thermal stress, which in turn may cause a complete device failure. For example, bending, flexing, vibration, and a difference in coefficient of thermal expansion between the substrate and BGA may potentially cause the solder joints to fracture. There exists a need to develop a feasible and efficient technique that reinforces the solder joints to prevent failure.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In some aspects, the techniques described herein relate to a method of fabricating an electronic assembly, including: forming a supporting member by applying a first adhesive layer to an interior surface of a supporting frame and a second adhesive layer to a bottom surface of the supporting frame; attaching, through the first adhesive layer, the supporting member to a component including a ball grid array of solder balls, such that the interior surface of the supporting frame covers a portion of a first side surface of the component and a portion of the bottom surface of the component; mounting, through the second adhesive layer, the supporting member to a substrate including an array of contact pads whose pattern matches the ball grid array on the component; and curing the second adhesive layer, wherein the curing includes connecting the solder balls to the contact pads by reflow soldering the solder balls at a temperature higher than a melting point of the solder balls.

In some aspects, the techniques described herein relate to a method, wherein the interior surface of the supporting frame covers a portion of a second side surface of the component, the second side surface being adjacent to the first side surface and the bottom surface of the component.

In some aspects, the techniques described herein relate to a method, wherein the interior surface of the supporting frame covers a portion of a top surface of the component.

In some aspects, the techniques described herein relate to a method, further including attaching the supporting member to a corner of the component.

In some aspects, the techniques described herein relate to a method, further including attaching additional supporting members to one or more corners and/or one or more edges of the component.

In some aspects, the techniques described herein relate to a method, further including semi-curing at least one of the first adhesive layer and the second adhesive layer before mounting the supporting member to the substrate.

In some aspects, the techniques described herein relate to a method, wherein the supporting frame is made of a metal or metal alloy.

In some aspects, the techniques described herein relate to an electronic assembly, including: a component including a ball grid array of solder balls; a substrate including an array of contact pads whose pattern matches the ball grid array on the component; and a supporting member between the component and the substrate, wherein the supporting member includes: a supporting frame; a first adhesive layer on an interior surface of a supporting frame; and a second adhesive layer on a bottom surface of the supporting frame, wherein the interior surface of the supporting frame covers a portion of a first side surface of the component and a portion of the bottom surface of the component, and wherein the supporting member is attached to the component through the first adhesive layer and to the substrate through the second adhesive layer.

In some aspects, the techniques described herein relate to an electronic assembly, wherein the interior surface of the supporting frame covers a second side surface of the component, the second side surface being adjacent to the first side surface and the bottom surface of the component.

In some aspects, the techniques described herein relate to an electronic assembly, wherein the interior surface of the supporting frame covers a portion of a top surface of the component.

In some aspects, the techniques described herein relate to an electronic assembly, wherein the supporting frame is attached to a corner of the component.

In some aspects, the techniques described herein relate to an electronic assembly, wherein additional supporting members are attached to one or more corners and/or one or more edges of the component.

In some aspects, the techniques described herein relate to an electronic assembly, wherein the supporting frame is made of a metal or metal alloy.

Other aspects and advantages of the claimed subject matter will be apparent from the following description and the appended claims.

### BRIEF DESCRIPTION OF THE DRAWINGS

FIG. 1 shows a cross-sectional view of an electronic assembly in accordance with one or more embodiments of the present disclosure.

FIG. 2 shows the disposition of the supporting member in accordance with one or more embodiments of the present disclosure.

FIGS. 3A-3F show supporting members in accordance with one or more embodiments of the present disclosure.

FIG. 4 shows a cross-sectional view of an electronic assembly in accordance with one or more embodiments of the present disclosure.

FIG. 5 is a flowchart of a surface mount method for an electronic assembly in accordance with one or more embodiments of the present disclosure.

### DETAILED DESCRIPTION OF THE INVENTION

Specific embodiments of the present disclosure will now be described in detail below with reference to the accompanying drawings. Like elements in the various figures are denoted by like reference numerals for consistency.

In the following detailed description of embodiments of the disclosure, numerous specific details are set forth to provide a more thorough understanding of the invention. However, it will be apparent to one of ordinary skill in the art that the invention may be practiced without these specific details. In other instances, well-known features have not been described in detail to avoid unnecessarily complicating the description.

One or more embodiments of the present disclosure relate to supporting members, electronic assemblies including supporting members, and surface mount methods for electronic assemblies that include supporting members. Embodiments of the present disclosure provide advantageous effects in strengthening the solder joints, reinforcing the electronic assembly's resistance, absorbing the thermal expansion mismatch between the component and the substrate in the electronic assembly, so as to avoid fracturing when subject to mechanical and thermal stress. In addition, embodiments of the present disclosure enable one-step reflow soldering and adhesive curing, including electronic assemblies and methods utilizing a double-side coated supporting member between the component and the substrate.

In the present disclosure, a thickness direction of a substrate is defined as a vertical direction Z. One direction perpendicular to the vertical direction Z indicates a direction X and another direction perpendicular to both directions of the vertical direction Z and the direction X indicates a direction Y. Along the vertical direction Z, a component side and a substrate side, respectively, are referred to as upper (top) and lower (bottom) sides. A horizontal plane refers to any plane along direction X and direction Y, for example, a plane parallel to a top surface of the substrate. A vertical plane refers to any plane along direction Z, for example, a plane perpendicular to a top surface of the substrate. Moreover, a planar view means to view a target object from the vertical direction Z. A cross-sectional view refers to a sectional view of the target object when cut apart along a plane in the vertical direction Z.

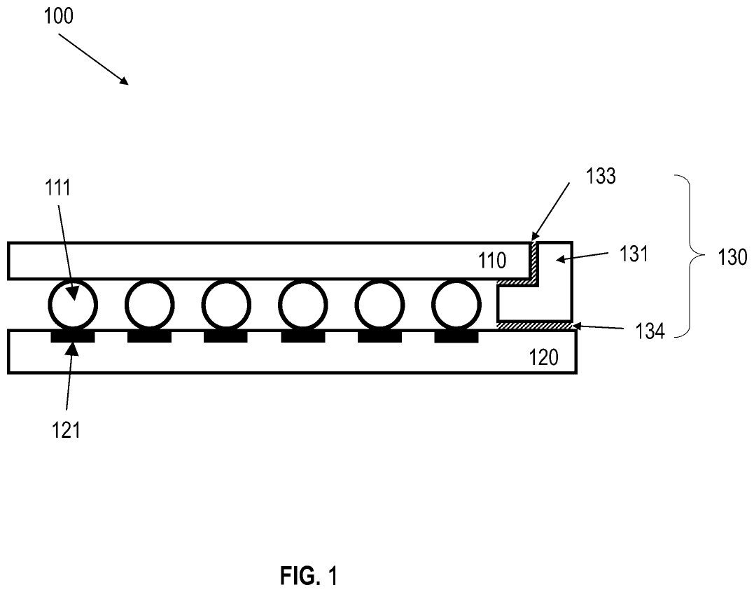

An “electronic assembly” in the present disclosure refers to a process of collecting, soldering, and/or integrating electronic components and circuits to carry out one or more tasks, as well as a product fabricated by such a process. FIG. 1 shows an electronic assembly 100 in accordance with one or more embodiments of the present disclosure. The electronic assembly 100 comprises a component 110, a substrate 120, and a supporting member 130.

The component 110 may be an electronic component, which can be any basic discrete device or physical entity in an electronic system used to affect electrons and/or their associated fields, or an integrated circuit (IC) component, which is an assembly of electronic components on a flat semiconductor material (e.g., a silicon wafer) connected together to achieve a common goal. Examples of the component 110 may include resistors, capacitors, inductors, discrete semiconductors, and integrated circuits. In one or more embodiments, the component 110 may be a microprocessor, for example, a central processing unit.

An array of solder balls 111 (also referred to as BGA) may be soldered to a bottom surface of the component 110 facing the substrate 120. The solder balls 111 are solid metal spheres, with a diameter varying based on component design, depending on a desired separation distance to prevent bridging defects or shorts and/or a desired density of electronics to ensure high performance. The diameter of the solder balls 111 may range from about 100 μm to about 1000 μm, or from about 200 μm to about 800 μm. The solder balls 111 may be made of metal or metal alloy and may comprise, for example, tin (Sn), silver (Ag), copper (Cu), bismuth (Bi), or a combination thereof.

The substrate 120 comprises an array of contact pads 121 that have the same pattern as the solder balls 111. The contact pads 121 may be made of metal or metal alloy, for example, tin (Sn), silver (Ag), gold (Au), copper (Cu), nickel (Ni), palladium (Pd), or a combination thereof.

The component 110 and the substrate 120 are connected through a reflow soldering process, in which the solder balls 111 are heated to melt, for example using a reflow oven or by an infrared heater, such that surface tension causes the molten solder balls to hold the component 110 in alignment with the substrate 120 at certain separation distance defined by a size of the solder balls 111. After the solder balls cool and solidify, each contact pad 121 is in connection with a corresponding solder ball 111, such that the component 110 and the substrate 120 are electrically connected through the solder balls 111 and the contact pads 121.

The supporting member 130 includes a supporting frame 131, a first adhesive layer 133, and a second adhesive layer 134. The supporting frame 131 includes a bottom horizontal portion disposed between a bottom surface of the component 110 and a top surface of the substrate 120 and a vertical portion covering a portion of a side surface of the component 110. The supporting frame 131 may be made of a rigid material. In one or more embodiments, the supporting frame 131 may be made of a metal of metal alloy, such as aluminum, magnesium, and stainless steel, or a polymer.

The first adhesive layer 133 is disposed at an interior surface of the supporting frame 131 that faces the component 110. The interior surface covers a portion of the bottom surface of the component 110 and a portion of the side surface of the component 110. The second adhesive layer 134 is disposed at a bottom surface of the supporting frame 131 between the supporting frame 131 and the top surface of the substrate 120. An adhesive may be used for the first adhesive layer 133 and/or the second adhesive layer 134, and has flowability under room temperature or low temperature and cures under elevated temperatures to form a uniform and void-free layer. The adhesives used for the first adhesive layer 133 and the second adhesive layer 134 may be the same, or may be different. The adhesives may be a polymer, for example, epoxy, silicone, and acrylic. In one or more embodiments, the adhesives used for the first adhesive layer 133 and the second adhesive layer 134 may be single component adhesives that are cured thermally, for example, epoxy resins. In other embodiments, one adhesive used for the first and second adhesive layers is a twin-component adhesive, which is semi-cured under ultraviolet light or heat and cured thermally, while the other adhesive used for the first and second adhesive layers is a single component adhesive which is cured thermally. For example, a first adhesive used in the first adhesive layer may be composed of an acrylic acid and a second adhesive used in the second adhesive layer may be composed of an epoxy resin.

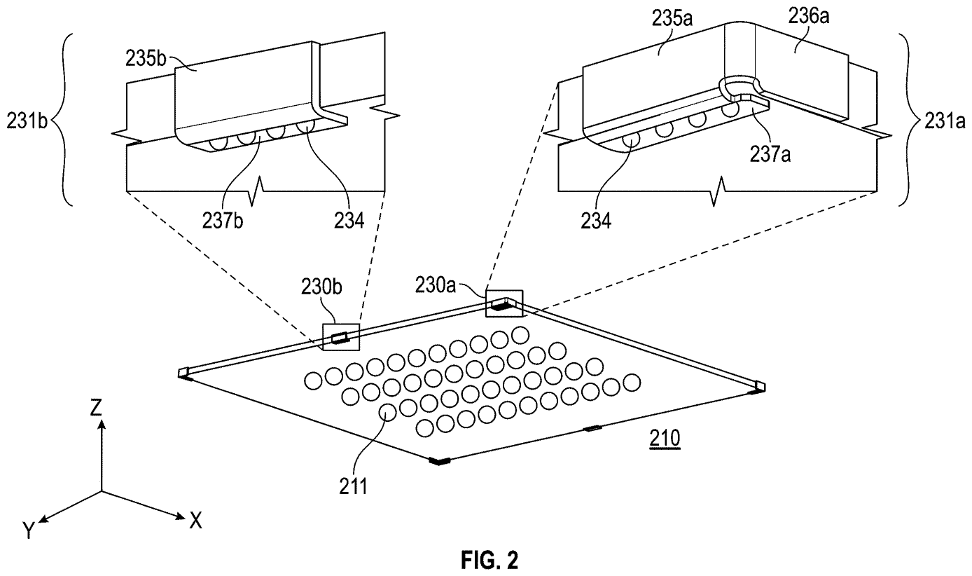

As shown in FIG. 1, the component 110 and the substrate 120 are electrically connected through the solder balls 111 and the contact pads 121, and are structurally supported by the supporting member 130. The supporting member 130 may be disposed at, for example, an edge and/or a corner of the component, because edges and/or corners may experience a higher stress, mechanically or thermally. FIG. 2 shows the disposition of the supporting member 130 at an edge and a corner of the component.

As shown in FIG. 2, a component 210 may include an array of solder balls 211 at a bottom surface of the component 210. A supporting member may be disposed at a corner of the component 210, such as supporting member 230a, or at an edge of the component, such as supporting member 230b. The supporting member may be disposed without interfering with the solder balls and may be adjusted based on the design of electronics. In one or more embodiments, a single piece of supporting member may be disposed to cover one or more corners and edges of the component 210. For example, one single piece of supporting member may cover all four corners and four edges of the component 210. In one or more embodiments, a plurality of supporting members may be dispersedly disposed at each corner and/or each edge of the component 210, and a number of supporting members may be adjusted as needed.

The supporting member 230a may include a supporting frame 231a, a first adhesive layer (not shown in FIG. 2), and a second adhesive layer 234. The supporting frame 231a may include a first vertical sheet 235a covering a portion of a first side surface of the component 210, a second vertical sheet 236a covering a portion of a second side surface of the component 210, and a bottom horizontal sheet 237a covering a portion of a bottom surface of the component 210. The first side surface, the second side surface, and the bottom surface of the component 210 are adjacent to each other at a corner of the component 210. An upper edge of the first vertical sheet 235a and/or an upper edge of the second vertical sheet 236a may align with a top surface of the component 210. Alternatively, in some implementations, the upper edges of the first vertical sheet 235a and the second vertical sheet 236a may extend to be higher or lower than the top surface of the component 210. The bottom horizontal sheet 237a may be coupled to the first vertical sheet 235a at a lower edge of the first vertical sheet 235a. A lower edge of the second vertical sheet 236a may align with a bottom surface of the component 210. Alternatively, in some implementations, the lower edge of the second vertical sheet 236a may extend to be higher or lower the bottom surface of the component 210. The first vertical sheet 235a, the second vertical sheet 236a, and the bottom horizontal sheet 237a may be fabricated by bending a single piece of sheet, or by molding a plurality of sheets together. A connection between any two of the sheets may have a rounded edge, as shown in FIG. 2. Alternatively, in other implementations, the connection between sheets may have a sharp or right-angle edge. The second vertical sheet 236a and the bottom horizontal sheet 237a may be separated from each other, as shown in FIG. 2, and may be coupled to each other in other implementations.

The supporting member 230a may be attached to the component 210 through a first adhesive layer (not shown) and to a substrate (not shown) through a second adhesive layer 234. For the supporting member 230a shown in FIG. 2, the first adhesive layer is applied to an interior surface of the supporting frame 231a. The interior surface includes surfaces of the first vertical sheet 235a, the second vertical sheet 236a, and the bottom horizontal sheet 237a that face the component. That is, the interior surface of the supporting frame 231a covers a portion of the first side surface, a portion of the second side surface, and a bottom surface of the component 210. While the first side surface and the second side surface of the component are shown as vertical in FIG. 2, it is not intended to be limiting. In some implementations, the side surfaces of the component may be angled or have other shapes, and the supporting frame may be modified to accommodate the shape of the component.

The supporting member 230b may include a supporting frame 231b, a first adhesive layer (not shown in FIG. 2), and a second adhesive layer 234. The supporting frame 231b may include a first vertical sheet 235b covering a portion of a first side surface of the component 210 and a bottom horizontal sheet 237b covering a portion of a bottom surface of the component 210. An upper edge of the first vertical sheet 235b may align with a top surface of the component 210. Alternatively, in some implementations, the upper edges of the first vertical sheet 235b may extend to be higher or lower than the top surface of the component 210. The bottom horizontal sheet 237b may be coupled to the first vertical sheet 235b at a lower edge of the first vertical sheet 235b. The first vertical sheet 235a and the bottom horizontal sheet 237a may be fabricated by bending a single piece of sheet, or by molding a plurality of sheets together. A connection between the sheets may have a rounded edge, as shown in FIG. 2. Alternatively, in other implementations, the connection between sheets may have a sharp and/or right-angle edge.

The supporting member 230b may be attached to the component 210 through a first adhesive layer (not shown) and to a substrate (not shown) through a second adhesive layer 234. For the supporting member 230b shown in FIG. 2, the first adhesive layer is applied to an interior surface of the supporting frame 231b. The interior surface includes surfaces of the first vertical sheet 235b and the bottom horizontal sheet 237b that face the component. That is, the interior surface of the supporting frame 231b covers a portion of the first side surface and a bottom surface of the component 210. In one or more embodiments, the first side surface is vertical, such that the first vertical sheet 235a is vertically arranged.

The supporting members 230a and 230b are mounted to the substrate (not shown in FIG. 2) through the second adhesive layer 234. The adhesive used for the second adhesive layer 234 may have flowability under room temperature or low temperature and cure under elevated temperatures to form a uniform and void-free layer. The second adhesive layer 234 is shown as droplets in FIG. 2. However, one having ordinary skill in the art would recognize that the configuration of the second adhesive layer 234 is not limited by the figure. The second adhesive layer 234 may be droplets, a film, or any other configuration known in the art. In some implementations, an adhesive that is in a liquid phase may be applied by drop casting, spray coating, or electrodeposition. In some implementations, an adhesive may be applied by immersing the supporting frame in an adhesive solution, followed by a semi-curing process to immobilize the adhesive. In some implementations, an adhesive is applied simply by dispensing droplets on a surface of the sheet.

The supporting members 230a and 230b each represent one or more embodiments of the present disclosure. While only the two configurations are shown in FIG. 2, one having ordinary skill in the art would recognize that many modifications are possible in the example embodiments without materially departing from this invention and that a variety of shape, size, materials, and disposition of the supporting member may be applied.

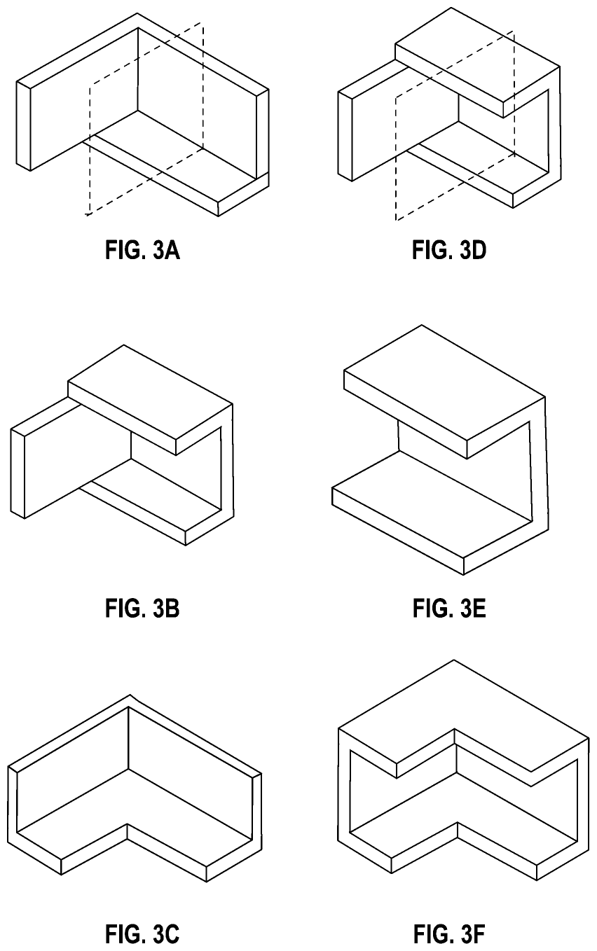

FIGS. 3A-3F show a variety of configurations for the supporting frame. According to one or more embodiments, the supporting member may be disposed at corners or edges of the component. Thus, the supporting frame may be designed to have a number of sheets adapted to the shapes of a corner or an edge. For example, the supporting member shown in FIG. 3A includes two vertical sheets and a bottom horizontal sheet. A cross-sectional view of the supporting member, when disposed in electronic assemblies described herein and cut apart by plane I, may have the cross-sectional view as shown in FIG. 1. The supporting member of FIG. 3A has a same configuration as the supporting member 230a disposed at a corner of the component, as shown in FIG. 2.

In one or more embodiments, the supporting member includes a vertical sheet and a bottom horizontal sheet, as shown in FIG. 3B. The supporting member has a same configuration as the supporting member 230b disposed at an edge shown in FIG. 2.

While the sheets constituting the supporting frames of FIGS. 3A and 3B have a rectangular shape, it is not intended to be limited thereby. According to one or more embodiments, the supporting member may have two vertical sheets with a rectangular shape and a bottom horizontal sheet having a polygon shape, as shown in FIG. 3C.

In one or more embodiments, the supporting frame includes a top sheet that covers a top surface of the component. For example, FIG. 3D shows a supporting frame having two vertical sheets, a bottom horizontal sheet, and a top horizontal sheet. The top horizontal sheet is coupled to the upper edges of the two vertical sheets. FIG. 3E shows a supporting frame having a vertical sheet, a bottom horizontal sheet, and a top horizontal sheet that is coupled to an upper edge of the vertical sheet. FIG. 3F shows a supporting frame having two vertical sheets, a bottom horizontal sheet, and a top horizontal sheet. The bottom horizontal sheet and top horizontal sheet both have a polygon shape.

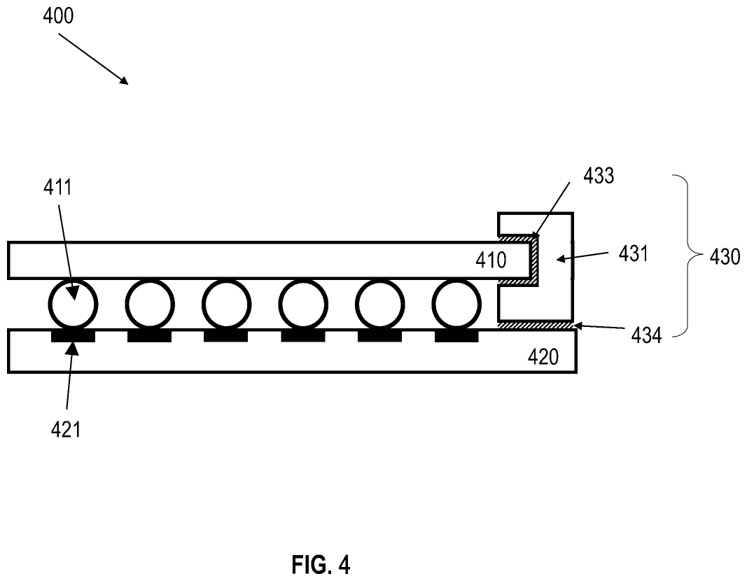

A cross-sectional view of a supporting member having a top horizontal sheet may have a configuration as shown in FIG. 4. For example, when an electronic assembly includes the supporting member of FIG. 3D and is cut apart by plane II, the cross-sectional view of the electronic assembly may be shown in FIG. 4. FIG. 4 shows an electronic assembly 400 including a supporting frame with a top horizontal sheet. One or more like elements in the figures are denoted by like reference numerals, and are not described repeatedly herein.

The electronic assembly 400 includes a component 410, a substrate 420, and a supporting member 430. An array of solder balls 411 are soldered to a bottom surface of the component 410 facing the substrate 420. An array of contact pads 421 is disposed on the substrate 420, having the same pattern as the solder balls 411. The component 410 and the substrate 420 are connected through a reflow soldering process. After the solder balls 411 cool and solidify, each contact pad 421 is in connection with a corresponding solder ball 411, such that the component 410 and the substrate 120 are electrically connected through the solder balls 411 and the contact pads 421.

The supporting member 430 includes a supporting frame 431, a first adhesive layer 433, and a second adhesive layer 434. The supporting frame 431 has a bottom horizontal portion disposed between a bottom surface of the component 410 and a top surface of the substrate 420, a top horizontal portion disposed on a top surface of the component 410, and a vertical portion covering a portion of a side surface of the component 410.

The first adhesive layer 433 is disposed at an interior surface of the supporting frame 431 that faces the component 410. The interior surface covers a portion of the bottom surface of the component 410, a portion of the top surface of the component 410, and a portion of the side surface of the component 410. The second adhesive layer 434 is disposed at a bottom surface of the supporting frame 431 between the supporting frame 431 and the top surface of the substrate 420. One or more adhesives may be used for the first adhesive layer 433 and/or the second adhesive layer 434, which has flowability under room temperature or low temperature and cures under elevated temperatures to form a uniform and void-free layer.

The component 410 and the substrate 420 are electrically connected through the solder balls 411 and the contact pads 421, and are structurally supported by the supporting member 430. The supporting member 430 may be disposed at, for example, an edge and/or a corner of the component 410, because edges and/or corners may experience a higher stress, mechanically or thermally.

While only a few configurations are shown in FIGS. 1-4, one having ordinary skill in the art would recognize that the top horizontal sheet, the bottom horizontal sheet, and the one or more vertical sheets of the supporting frame may have other shapes and sizes. The sheets in the supporting frame may be integrated as one piece, for example, by bending a single piece of sheet or by welding a plurality of sheets.

A thickness of each sheet in the supporting frame depends on the design of the electronic assembly and may range from about 100 μm to about 1000 μm, or from about 200 μm to about 600 μm. A thickness of the first adhesive layer may range from about 20 μm to about 200 μm. A thickness of the second adhesive layer may range from about 20 μm to about 200 μm.

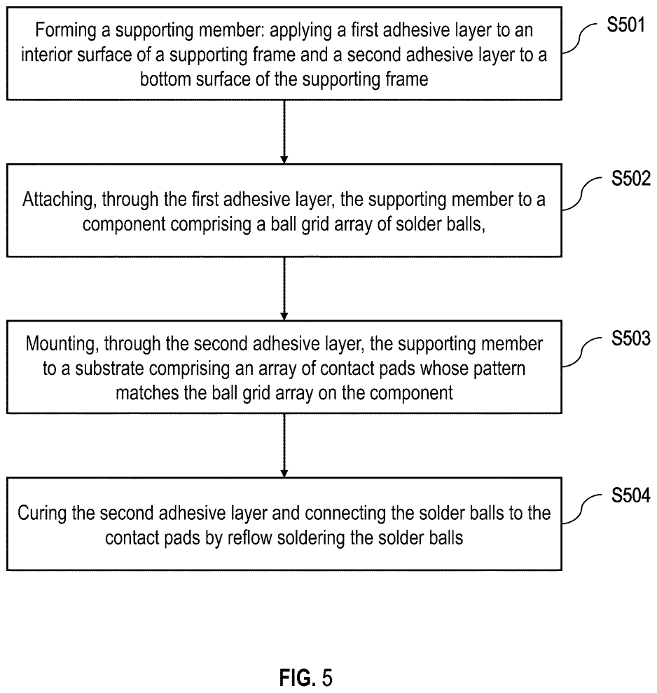

The electronic assembly described in one or more embodiments may be fabricated by a surface mount method shown in the flowchart of FIG. 5. The surface mount method may include step S501, forming a supporting member by applying a first adhesive layer to an interior surface of a supporting frame and a second adhesive layer to a bottom surface of the supporting frame.

An adhesive used for the first adhesive layer may be the same with or may be different from that used in the second adhesive layer. In some implementations, an adhesive that is in a liquid phase may be applied by drop casting, spray coating, or electrodeposition. In some implementations, an adhesive may be applied by immersing the supporting frame in an adhesive solution, followed by a semi-curing process to immobilize the adhesive and prevent the adhesive from dropping or misalignment during assembly processes. In some implementations, an adhesive is applied simply by dispensing droplets on the surface of the supporting frame. The first adhesive layer and the second adhesive layer may be applied one after the other, or may be applied at the same time.

The surface mount method of FIG. 5 may include step S502, attaching, through the first adhesive layer, the supporting member to a component comprising a ball grid array of solder balls, such that the interior surface of the supporting frame covers a portion of a first side surface of the component and a portion of the bottom surface of the component. In some implementations, the interior surface of the supporting frame further covers a portion of a second side surface and/or a portion of a top surface of the component. The interior surface of the supporting frame may include all surfaces of sheets that face the component. The supporting member may be attached to one or more corners and/or one or more edges of the component, because these areas may experience a higher stress, mechanically or thermally. In one or more embodiments, a plurality of supporting members may be attached to corners (e.g., all four corners) and/or edges of the component. For example, four supporting members may be attached to the four corners of the component, and a desired number (e.g., one, two, three, etc.) of supporting members may be attached to each edge of the component. A shape, size, disposition, and number of supporting members may be subject to change in practical applications. The supporting frame may be an integrated structure including a plurality of sheets. One or more sheets may be vertical, so as to cover the portion of the side surface of the component, or may be horizontal, so as to cover the portion of the bottom surface and/or top surface of the component. In one or more embodiments, the attaching may include aligning the supporting member and the component using any known technique in the art. In one or more embodiments, the attaching may include a pick-and-place process that is commonly known in the art.

The surface mount method of FIG. 5 may include step S503, mounting, through the second adhesive layer, the supporting member to a substrate comprising an array of contact pads whose pattern matches the ball grid array on the component. In one or more embodiments, the mounting may be performed in a similar manner as the attachment of the supporting member to the component.

During the attaching in S502 and mounting in S503, the adhesive(s) in the first adhesive layer and/or the second adhesive layer has the flowability to fill the gaps between the component and the supporting member and between the substrate and the supporting member, respectively. In one or more embodiments, at least one of the first adhesive layer and the second adhesive layer may be semi-cured before mounting the supporting member to the substrate, such that the adhesive(s) is immobilized on the surfaces of the supporting frame yet still has flowability to fill the gap. The surface mount method of FIG. 5 may include step S504, curing the first adhesive layer and the second adhesive layer. The curing of the first adhesive layer and the second adhesive layer may be performed at the same time with reflow soldering of the solder balls. A heating system may include a reflow oven and an infrared lamp, providing elevated temperatures for curing and for reflow soldering.

A heating profile for curing and reflow soldering may include a first stage when the temperature is increased from about room temperature to an elevated temperature above a melting point of the solder balls, a second stage when the temperature is maintained at the elevated temperature for a certain period, and a third stage of cooling. In the first stage, the temperature may increase at a rate of about 1-5° C. per second, or about 1-3° C. per second. The elevated temperature may be in a range of about 140° C. to about 250° C. The solder balls may melt under the elevated temperature, and surface tension causes the molten solder balls to hold the component in alignment with the substrate at a certain separation distance. After the solder balls cool and solidify, each contact pad is in connection with a corresponding solder ball, such that the component and the substrate are electrically connected through the solder balls and the contact pads. At the same time, the second adhesive layer is cured, securing the supporting member to both of the component and the substrate, thus providing advantageous effects in strengthening the solder joints, reinforcing the electronic assembly's resistance, absorbing the thermal expansion mismatch between the component and the substrate, so as to avoid fracturing when subject to mechanical and thermal stress.

While only a few configurations are shown in the accompanying figures, one having ordinary skill in the art would recognize that many modifications are possible in the example embodiments without materially departing from this invention. Accordingly, all such modifications are intended to be included within the scope of this disclosure as defined in the following claims.

1. A method of fabricating an electronic assembly, comprising:
forming a supporting member by applying a first adhesive layer to an interior surface of a supporting frame and a second adhesive layer to a bottom surface of the supporting frame;
attaching, through the first adhesive layer, the supporting member to a component comprising a ball grid array of solder balls, such that the interior surface of the supporting frame covers a portion of a first side surface of the component and a portion of the bottom surface of the component;
mounting, through the second adhesive layer, the supporting member to a substrate comprising an array of contact pads whose pattern matches that of the ball grid array; and
curing the first adhesive layer and the second adhesive layer,
wherein the curing comprises connecting the solder balls to the contact pads by reflow soldering the solder balls at a temperature higher than a melting point of the solder balls.

2. The method of claim 1, wherein the interior surface of the supporting frame covers a portion of a second side surface of the component, the second side surface being adjacent to the first side surface and the bottom surface of the component.

3. The method of claim 1, wherein the interior surface of the supporting frame covers a portion of a top surface of the component.

4. The method of claim 1, further comprising attaching the supporting member to a corner or an edge of the component.

5. The method of claim 1, further comprising attaching additional supporting members to one or more corners and/or one or more edges of the component.

6. The method of claim 1, further comprising semi-curing at least one of the first adhesive layer and the second adhesive layer before mounting the supporting member to the substrate.

7. The method of claim 1, wherein the supporting frame is made of a metal or metal alloy.

8. An electronic assembly, comprising:
a component comprising a ball grid array of solder balls;
a substrate comprising an array of contact pads whose pattern matches the ball grid array on the component; and
a supporting member between the component and the substrate,
wherein the supporting member comprises:
a supporting frame;
a first adhesive layer on an interior surface of a supporting frame; and
a second adhesive layer on a bottom surface of the supporting frame,
wherein the interior surface of the supporting frame covers a portion of a first side surface of the component and a portion of the bottom surface of the component, and
wherein the supporting member is attached to the component through the first adhesive layer and to the substrate through the second adhesive layer.

9. The electronic assembly of claim 8, wherein the interior surface of the supporting frame covers a second side surface of the component, the second side surface being adjacent to the first side surface and the bottom surface of the component.

10. The electronic assembly of claim 8, wherein the interior surface of the supporting frame covers a portion of a top surface of the component.

11. The electronic assembly of claim 8, wherein the supporting frame is attached to a corner or an edge of the component.

12. The electronic assembly of claim 8, wherein additional supporting members are attached to one or more corners and/or one or more edges of the component.

13. The electronic assembly of claim 8, wherein the supporting frame is made of a metal or metal alloy.
